(19) United States
(12) Patent Application Publication
(10) Pub. No.: US 2025/0133923 A1
(43) Pub. Date: Apr. 24, 2025

(54) ORGANIC LIGHT EMITTING DISPLAYING APPARATUS

(71) Applicant: LG DISPLAY CO., LTD., Seoul (KR)

(72) Inventors: KaKyung KIM, Paju-si, Gyeonggi-do (KR); JoungMi CHOI, Paju-si, Gyeonggi-do (KR)

(73) Assignee: LG DISPLAY CO., LTD., Seoul (KR)

(21) Appl. No.: 18/919,870

(22) Filed: Oct. 18, 2024

(30) Foreign Application Priority Data
Oct. 20, 2023 (KR) 10-2023-0141018

(51) Int. Cl. H10K 59/127; H01L 27/12; H10K 59/121; H10K 59/123; H10K 77/10; H10K 102/00

(52) U.S. Cl. CPC H10K 59/1275; H10D 86/411; H10D 86/441; H10D 86/60; H10K 59/1213; H10K 59/123; H10K 77/111; H10K 2102/311

(57) ABSTRACT

An organic light emitting display device includes a TFT substrate on which a display area is defined, a thin film encapsulation layer disposed on the TFT substrate such that the thin film encapsulation layer covers the display area, and a bottom pad disposed on the lower surface of the TFT substrate, and is configured to displays an image; a flexible printed circuit board mounted on the bottom pad of the panel assembly; and a connection line that is disposed on at least one of the upper, lower, left side, and right side surfaces of the TFT substrate, and interconnects an upper signal line disposed on the top surface of the TFT substrate and the bottom pad disposed on the lower surface of the TFT substrate.

### CROSS-REFERENCE TO RELATED APPLICATION

This application claims the priority of Republic of Korea Patent Application No. 10-2023-0141018, filed on Oct. 20, 2023, which is hereby incorporated by reference in its entirety.

### BACKGROUND

### Field of the Disclosure

The present disclosure relates to electronic devices (or electronic apparatuses) with displays, and more specifically, to an organic light emitting display device (or an organic light emitting display apparatus).

### Description of the Background

As the information-oriented society has been developed, display technology have developed rapidly to meet various needs for visually expressing information, data, applications, and the like. Indeed, various types of display devices with excellent performance such as thin package, light weight, low power consumption, and the like have been developed.

As such display devices, liquid crystal display (LCD) devices, quantum dot (QD) display devices, organic light emitting diode (OLED) devices, field emission display (FED) devices, and the like are increasingly used.

A display device may include a display panel and a plurality of components to provide various functions. For example, one or more display driving circuits for controlling the display panel may be included in a display assembly.

The display driving circuits may include gate drivers, light emitting (source) drivers, power (VDD) routing, electrostatic discharge (ESD) circuits, multiplex (MUX) circuits, data signal lines, cathode contacts, and other functional elements.

A plurality of peripheral circuits may be included in the display assembly to provide various types of additional functions, for example, touch sensing, fingerprint identification functions, and the like.

Some components may be disposed inside of the display panel, or in a surrounding area outside of a display area, which may be referred to as a non-display area or an inactive area.

When designing display devices, a size of corresponding display area is considered as one of important design factors. Further, a high ratio of the size of display area to the size of non-display area, which is sometimes referred to as the screen-to-bezel ratio, has been increasingly important. However, disposing some of such peripheral circuits inside of a display assembly may require a greater non-display area, this leading the size of a display panel to be considerably increased. Thus, the greater non-display area may cause the display panel to become bigger, and in turn, this may present an obstacle to integrating the display panel into the housing of electronic devices.

The greater non-display area may also require large masking to cover a significant portion of the display panel, and this may lead to aesthetically unappealing of the device.

A technology for bending the bezel using a flexible board has been developed so that some components may be disposed on a separate flexible printed circuit board, but such display devices still suffer from reducing the bezel.

### SUMMARY

To address these issues, one or more aspects of the present disclosure may provide an organic light emitting display device capable of minimizing a side bezel area.

One or more aspects of the present disclosure may provide an organic light emitting display device capable of reducing a bezel area without affecting display performance.

One or more aspects of the present disclosure may provide an organic light emitting display device capable of reducing a bezel area without bending a TFT substrate.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, an organic light emitting display device includes a panel assembly that includes a thin film transistor (TFT) substrate on which a display area is defined, a thin film encapsulation layer disposed on the TFT substrate such that the thin film encapsulation layer covers the display area, and a bottom pad disposed on or under the lower surface of the TFT substrate, and is configured to displays an image; a flexible printed circuit board mounted on or bonded to the bottom pad of the panel assembly; and a connection line that is disposed on at least one of the upper, lower, left side, and right side surfaces of the TFT substrate, and interconnects an upper signal line disposed on the upper surface of the TFT substrate and the bottom pad disposed on or under the lower surface of the TFT substrate.

In another aspect of the present disclosure, an organic light emitting display device includes an upper signal line disposed on the upper surface of a TFT substrate; a circuit device located on or under the lower surface of the TFT substrate, and including a driving element and other components for driving the panel assembly; and a connection line disposed on a side surface of the TFT substrate, and interconnecting the upper signal line and the circuit device.

According to one or more aspects of the present disclosure, an organic light emitting display device may be provided that is capable of minimizing, or almost eliminating, an area occupied by a side bezel area.

According to one or more aspects of the present disclosure, an organic light emitting display device may be provided that is capable of reducing a bezel area without affecting display performance.

According to one or more aspects of the present disclosure, an organic light emitting display device may be provided that is capable of reducing a bezel area without bending a TFT substrate.

According to one or more aspects of the present disclosure, an organic light emitting display device may be provided that is capable of reducing production energy and manufacturing costs by disposing a connection line, which electrically interconnecting an upper signal line and circuit elements located under or on the lower surface of a TFT substrate, on a side of the TFT substrate through a simple process.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

In the drawings:

FIG. 1 illustrates an example system configuration of a display device according to aspects of the present disclosure;

FIG. 2 illustrates an example schematic configuration of the display device according to aspects of the present disclosure;

FIG. 3 is a cross-sectional view illustrating the structure of an example flexible organic light emitting display device;

FIG. 4 is a cross-sectional view illustrating an example structure defining a circuit area on or under the lower surface of a substrate using through holes;

FIG. 5 is a cross-sectional view illustrating an example structure in the organic light emitting display device according to aspects of the present disclosure;

FIG. 6 is a cross-sectional view illustrating an example structure in a side portion of the organic light emitting display device according to aspects of the present disclosure;

FIG. 7 is a cross-sectional view illustrating another example structure in a side portion of the organic light emitting display device according to aspects of the present disclosure;

FIG. 8 is a perspective view illustrating an example side portion of the organic light emitting display device according to aspects of the present disclosure;

FIG. 9 illustrates an example structure in which different upper signal lines are connected to respective connection lines in the organic light emitting display device according to aspects of the present disclosure; and

FIGS. 10 to 14 illustrate example process diagrams for explaining a method of manufacturing the organic light emitting display device according to aspects of the present disclosure.

### DETAILED DESCRIPTION

Reference will now be made in detail to aspects of the present disclosure, examples of which may be illustrated in the accompanying drawings. In the following description, the structures, aspects, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example aspects of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only may the first element “be directly connected or coupled to” or “directly contact or overlap” the second element, but a third element may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

In addition, when any dimensions, relative sizes etc. are mentioned, it should be considered that numerical values for an elements or features, or corresponding information (e. g., level, range, etc.) include a tolerance or error range that may be caused by various factors (e. g., process factors, internal or external impact, noise, etc.) even when a relevant description is not specified. Further, the term “may” fully encompasses all the meanings of the term “may”.

Hereinafter, with reference to the accompanying drawings, various aspects of the present disclosure will be described in detail.

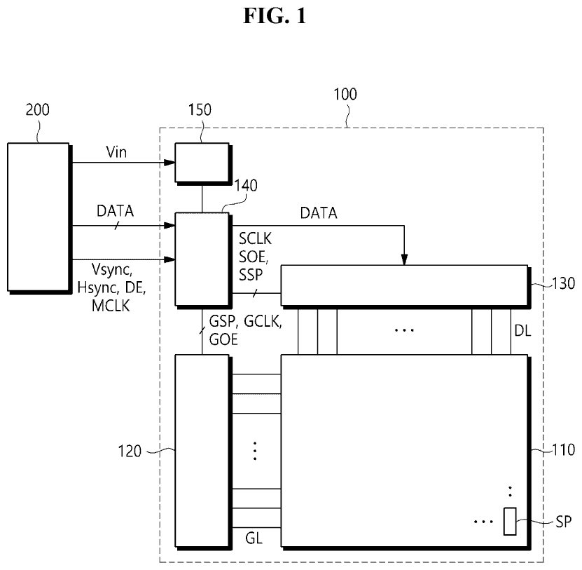

FIG. 1 illustrates an example system configuration of a display device 100 (e.g., an organic light emitting display device) according to aspects of the present disclosure.

Referring to FIG. 1, in one or more aspects, the display device 100 may include a display panel 110 and a display driving circuit as components for displaying an image. The display driving circuit may be a circuit for driving the display panel 110, and include a data driving circuit 130, a gate driving circuit 120, a display controller 140, and other circuit components.

The display panel 110 may include a substrate and a plurality of subpixels SP disposed on the substrate.

The substrate of the display panel 110 may include a display area DA allowing an image to be displayed and a non-display area NDA located outside of the display area DA.

In the display panel 110 according to aspects of the present disclosure, the non-display area NDA may have a very small area compared with the display area DA.

For example, the non-display area NDA may include a first non-display area located outside of the display area DA in a first direction, a second non-display area located outside of the display area DA in a second direction intersecting the first direction, a third non-display area located outside of the display area DA in a direction opposite to the first direction, and a fourth non-display area located outside of the display area DA in a direction opposite to the second direction. One or two non-display areas among the first to fourth non-display areas may include a pad area to which the data driving circuit 130 is connected or bonded. For example, among the first to fourth non-display areas, each of the remaining three or two non-display areas, which do not include the pad area, may have a very small size compared with the one or two non-display areas including the pad area.

In an aspect, a boundary area between the display area DA and the non-display area NDA may be bent, and thereby, the non-display area NDA may be located under the display area DA. In this aspect, when a user views the display device 100 in front thereof, all or most of the non-display area NDA may not be visible to the user.

Various types of signal lines for driving a plurality of subpixels SP may be disposed on the substrate of the display panel 110.

In one or more aspects, the display device 100 according to aspects of the present disclosure may be a liquid crystal display device, or the like, or a self-emission display device in which light is emitted from the display panel 110 itself. In an example where the display device 100 according to aspects of the present disclosure is the self-emission display device, each of the plurality of subpixels SP may include a light emitting element.

For example, the display device 100 according to aspects of the present disclosure may be an organic light emitting display device implemented with organic light emitting diodes (OLED) as light emitting elements. In another example, the display device 100 according to aspects of the present disclosure may be an inorganic light emitting display device implemented with inorganic material-based light emitting diodes as light emitting elements. In further another example, the display device 100 according to aspects of the present disclosure may be a quantum dot display device implemented with quantum dots, which are self-emission semiconductor crystals, as light emitting elements.

The structure of each of the plurality of subpixels SP may depend on types of display device 100. For example, in an example where the display device 100 is a self-emission display device including self-emission subpixels SP, each subpixel SP may include a self-emission light emitting element, one or more transistors, and one or more capacitors.

The various types of signal lines may include, for example, a plurality of data lines DL for carrying data signals (which may be referred to as data voltages or image signals), a plurality of gate lines GL for carrying gate signals (which may be referred to as scan signals), and the like.

In one or more aspects, the plurality of data lines DL and the plurality of gate lines GL may intersect one another. For example, each data line DL may intersect each gate line GL at a certain angle. Each of the plurality of data lines DL may be disposed to extend in a first direction, and each of the plurality of gate lines GL may be disposed to extend in a second direction. For example, the first direction may be a column or vertical direction, and the second direction may be a row or horizontal direction. In another example, the first direction may be the row or horizontal direction, and the second direction may be the column or vertical direction. Hereinafter, for convenience of explanation, discussions may be provided based on examples where each of a plurality of data lines DL is disposed in the column direction, and each of a plurality of gate lines GL is disposed in the row direction, but aspects of the present disclosure are not limited thereto.

The data driving circuit 130 may be a circuit for driving a plurality of data lines DL and may output data signals to the plurality of data lines DL.

The data driving circuit 130 may receive image data DATA in digital form from the display controller 140, convert the received image data DATA into data signals in analog form, and output converted data signals to the plurality of data lines DL.

In one or more aspects, the data driving circuit 130 may be connected to the display panel 110 using a tape-automated-bonding (TAB) technique, or connected to a conductive pad such as a bonding pad of the display panel 110 using a chip-on-glass (COG) technique or a chip-on-panel (COP) technique, or implemented in the display panel 110 using a chip-on-film (COF) technique.

The data driving circuit 130 may be located in, and/or electrically connected to, but not limited to, only one side or portion (e.g., an upper edge or a lower edge) of the display panel 110. In one or more aspects, the data driving circuit 130 may be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements.

The data driving circuit 130 may be connected to outside, or an edge, of the display area DA of the display panel 110, or be disposed in the display area DA of the display panel 110.

The gate driving circuit 120 may be a circuit for driving a plurality of gate lines GL and may output gate signals to the plurality of gate lines GL. The gate driving circuit 120 may receive various types of gate driving control signals GCS, and further, receive a first gate voltage corresponding to a turn-on level voltage and a second gate voltage corresponding to a turn-off level voltage. Thereby, the gate driving circuit 120 may generate gate signals and supply the generated gate signals to the plurality of gate lines GL.

In one or more aspects, the gate driving circuit 120 included in the display device 100 may be embedded into the display panel 110 using a gate-in-panel (GIP) technique. In an example where the gate driving circuit 120 is implemented using the gate-in-panel (GIP) technique, the gate driving circuit 120 may be disposed on the substrate of the display panel 110 during the manufacturing process of the display panel 110 or display device 100. In one aspect, the gate driving circuit 120 included in the display device 100 may be disposed in the display area DA of the display panel 110. In this implementation, for example, the gate driving circuit 120 may be disposed in, and/or electrically connected to, but not limited to, a first area (e. g., a left area or a right area of the display area DA) of the display area DA of the display panel 110. In another example, the gate driving circuit 120 may be disposed in, and/or electrically connected to, but not limited to, a first area (e. g., a left area or a right area of the display area DA) and a second area (e. g., the right area or the left area of the display area DA) of the display area DA of the display panel 110.

Herein, the gate driving circuit 120 embedded in the display panel 110 using the gate-in-panel (GIP) technique may also be referred to as a “gate-in-panel circuit.”

The display controller 140 may be a device for controlling the data driving circuit 130 and the gate driving circuit 120, and may control driving timing for the plurality of data lines DL and driving timing for the plurality of gate lines GL.

The display controller 140 may supply a data driving control signal DCS to the data driving circuit 130 to control the data driving circuit 130, and supply a gate driving control signal GCS to the gate driving circuit 120 to control the gate driving circuit 120.

The display controller 140 may receive image data input from a host system 150 and supply image data DATA readable by the data driving circuit 130 based on the input image data to the data driving circuit 130.

The display controller 140 may be implemented in a separate component from the data driving circuit 130, or incorporated in the data driving circuit 130 and thus implemented in an integrated circuit.

The display controller 140 may be a timing controller used in the typical display technology or a controller or a control device capable of performing other control functions in addition to the function of the typical timing controller. In one or more aspects, the display controller 140 may be a controller or a control device different from the timing controller, or a circuitry or a component included in the controller or the control device. The display controller 140 may be implemented using various circuits or electronic components such as an integrated circuit (IC), a field programmable gate array (FPGA), an application specific integrated circuit (ASIC), a processor, and/or the like.

The display controller 140 may be mounted on a printed circuit board, a flexible printed circuit, and/or the like and be electrically connected to the gate driving circuit 120 and the data driving circuit 130 through the printed circuit board, flexible printed circuit, and/or the like.

The display controller 140 may transmit signals to, and receive signals from, the data driving circuit 130 via one or more predefined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect the presence or absence of a touch by an object such as a finger, a pen and the like, or the location of the touch.

The touch sensing circuit may include a touch driving circuit configured to drive and sense the touch sensor and generate and output touch sensing data, and a touch controller capable of detecting the presence or absence of a touch or the location of the touch using the touch sensing data.

The touch sensor may include a plurality of touch electrodes. The touch sensor may further include a plurality of touch lines to electrically connect the plurality of touch electrodes to the touch driving circuit.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process.

The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit may supply a touch driving signal to at least one of a plurality of touch electrodes and generate touch sensing data by sensing at least one of the plurality of touch electrodes.

The touch sensing circuit may perform touch sensing using a self-capacitance sensing technique or a mutual-capacitance sensing technique.

In the example where the touch sensing circuit performs touch sensing using the self-capacitance sensing technique, the touch sensing circuit may perform touch sensing based on capacitance between each touch electrode and a touch object (e. g., a finger, a pen and the like). According to the self-capacitance sensing technique, each of a plurality of touch electrodes may serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing using the mutual-capacitance sensing technique, the touch sensing circuit may perform touch sensing based on a capacitance between touch electrodes. According to the mutual-capacitance sensing technique, a plurality of touch electrodes may be divided into driving touch electrodes and sensing touch electrodes. The touch driving circuit may drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display device 100 may further include a power supply circuit for supplying various types of power to the display driving circuit and/or the touch sensing circuit. In one or more aspects, the display device 100 according to aspects of the present disclosure may represent, but not limited to, a mobile terminal, such as a smart phone, a tablet, or the like, a monitor, a television (TV), or the like. Aspects of the present disclosure are not limited thereto. In one or more aspects, the display device 100 may be display devices, or include displays, of various types, sizes, and shapes for displaying information or images.

In one or more aspects, the display device 100 may further include an electronic device such as a camera (e.g., an image sensor), a sensor capable of detecting an object, and the like. For example, the sensor may be a sensor capable of detecting an object or a human body by receiving light such as infrared light, ultrasonic light, ultraviolet light or the like.

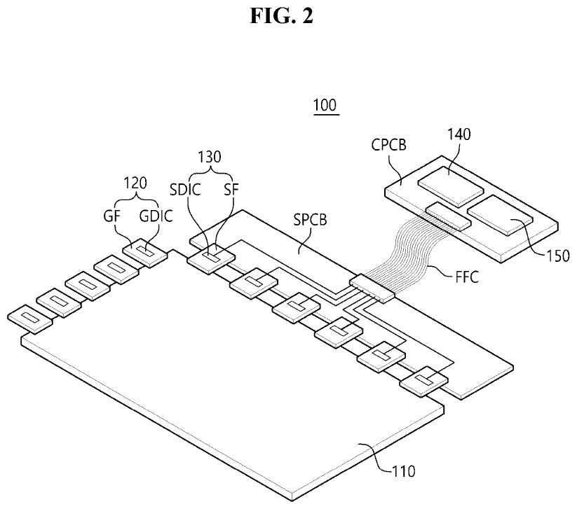

FIG. 2 illustrates an example schematic configuration of the display device 100 according to aspects of the present disclosure.

FIG. 2 illustrates that in the display device 100 according to aspects of the present disclosure, one or more source driver integrated circuits SDIC included in the data driving circuit 130 and one or more gate driver integrated circuits GDIC included in the gate driving circuit 120 are implemented using the chip-on-film (COF) technique among various techniques (the TAB, the COG, the COF, and the like).

Each of one or more gate driver integrated circuits GDIC included in the gate driving circuit 120 may be mounted on a respective gate film GF, and one side of each of the gate films GF may be electrically connected to the display panel 110. In one or more aspects, lines for electrically connecting a corresponding gate driver integrated circuit GDIC to the display panel 110 may be disposed on each gate film GF.

In these aspects, the gate driving circuit 120 may be located in only one side or portion (e.g., a left edge, a right edge, an upper edge, a lower edge, or the like), or in two sides or portions (e.g., a left edge and a right edge, an upper edge and a lower edge, or the like) of the display panel 110 according to design requirements. In one or more aspects, the gate driving circuit 120 may be embedded in a bezel area of the display panel 110, and be implemented in the gate-in-panel (GIP) type.

Each of one or more source driver integrated circuits SDIC included in the data driving circuit 130 may be mounted on a respective source film SF, and a first side of each source film SF may be electrically connected to the display panel 110. In one or more aspects, lines for electrically connecting a corresponding source driver integrated circuit SDIC to the display panel 110 may be disposed on each source film SF.

The display device 100 may include one or more printed circuit boards for circuit connection between one or more source driver integrated circuits SDIC and one or more other components or devices. The printed circuit boards may include, for example, at least one source printed circuit board SPCB, a control printed circuit board CPCB on which control components and various electrical devices are mounted, and the like.

In an aspect, a second opposing side of each source film SF on which a corresponding source driver integrated circuit SDIC is mounted may be connected to a source printed circuit board SPCB. For example, the first side of each source film SF on which a corresponding source driver integrated circuit SDIC is mounted may be electrically connected to the display panel 110, and the second opposing side of each source film SF may be electrically connected to a source printed circuit board SPCB.

The controller 140, the power management circuit (or a power management IC, 150), and the like may be mounted on the control printed circuit board CPCB. The controller 140 may control operations of the data driving circuit 130 and the gate driving circuit 120. The power management circuit 150 may supply power (e. g., various levels of driving voltages or various amounts of current) to the display panel 110, the data driving circuit 130, the gate driving circuit 120, and the like, and control a voltage level or a current amount supplied thereto.

In one or more aspects, the at least one source printed circuit board SPCB and the control printed circuit board CPCB may be electrically connected to each other through at least one connector, such as a flexible printed circuit FPC, a flexible flat cable FFC, and/or the like.

In these aspects, the at least one connector for electrically interconnecting the at least on source printed circuit board SPCB and the control printed circuit board CPCB may be variously designed or defined depending on sizes and types of the display device 100. In one or more aspects, the at least one source printed circuit board SPCB and the control printed circuit board CPCB may be integrated into one printed circuit board.

According to the aspects described above, the power management circuit 150 included in the display device 100 may supply a driving voltage required for display driving or characteristic value sensing to a source printed circuit board SPCB through a flexible printed circuit FPC or a flexible flat cable FFC. The driving voltage delivered to the source printed circuit board SPCB may be supplied to the display panel 110 through a source driver integrated circuit SDIC, this enabling at least on subpixel SP to be driven for emitting light or to be sensed.

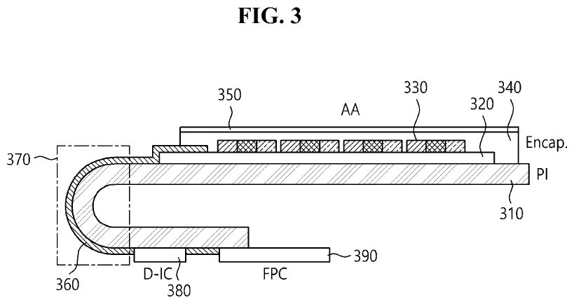

FIG. 3 is a cross-sectional view illustrating the structure of an example flexible organic light emitting display device.

FIG. 3 illustrates that the flexible organic light emitting display device has a structure in which a polyimide substrate 310 is bent at a side portion 370 of the display device. Referring to FIG. 3, for example, a source driver integrated circuit 380 and a flexible printed circuit board 390 may be disposed on the lower surface of the bent portion of the substrate 310.

In this example, an upper signal line 360 may extend, along the side portion 370, from the upper surface of the substrate 310 to the lower surface of the bent portion of the substrate 310, and be connected to the source driver integrated circuit 380 and the flexible printed circuit board 390 on the lower surface. An insulating layer 320 may be formed on the substrate 310. Subpixels 330 may be disposed on the insulating layer 320. A thin film encapsulation layer 340 may be disposed on the substrate 310 while covering the display area AA. A cover glass 350 may be disposed on the thin film encapsulation layer 340.

This implementation may represent a pixel-on-top (POT) structure (which may be applicable in mobile OLED products and allowing a pixel electrode to be formed on a protective layer of a TFT array substrate), and may be a structure in which the substrate, a transistor, and the pixel electrode are stacked. This implementation intends the reduction of the bottom bezel through the bending of the substrate 310 after the source driver integrated circuit 380 and the flexible printed circuit board 390 are mounted on the substrate 310, but this structure may be disadvantageous because an additional bezel area corresponding to such a bending area is still required.

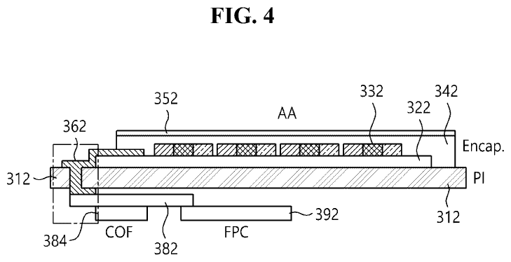

FIG. 4 is a cross-sectional view illustrating an example structure defining a circuit area on or under the lower surface of a substrate using through holes.

Referring to FIG. 4, in the organic light emitting display device, a through hole may be formed in a TFT substrate through dry etching, and the like, and an upper signal line 362 may be connected, through the through hole, from the upper surface of the substrate 312 to the flexible printed circuit 392 disposed on or under the lower surface of the substrate 312.

Thus, as the through hole is formed in a portion of the substrate, and the upper signal line is connected, through the through hole, to a circuit such as the flexible printed circuit 392 disposed on or under the bottom of the substrate, the bezel area may be minimized because the circuit is disposed on or under the bottom of the substrate without being disposed in the bezel area. An insulating layer 322 may be formed on the substrate 312. Subpixels 332 may be disposed on the insulating layer 322. A thin film encapsulation layer 342 may be disposed on the substrate 312 while covering the display area AA. A cover glass 352 may be disposed on the thin film encapsulation layer 342. A bottom pad 382 may be disposed on or under the lower surface of the substrate 312. One or more circuit devices 384 for processing driving signals may be mounted on the bottom pad 382 using the chip-on-film (COF) technique, and at least one connector (not shown) may be disposed in the bottom pad 382 to transmit external signals to the flexible printed circuit 392.

According to this implementation, a fine patterning process may be required to form a through hole penetrating the top and bottom of the substrate for each pad. When the fine patterning process is performed, a metal deposited on the wall of the through hole may be cracked in the pressing process of the modularization process.

To address the issues of the foregoing implementation as shown in FIG. 4, hereinafter, aspects applied in the display device 100 according to aspects of the present disclosure will be described below.

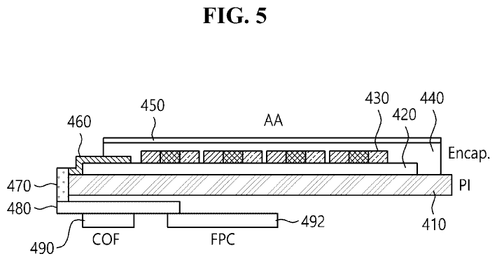

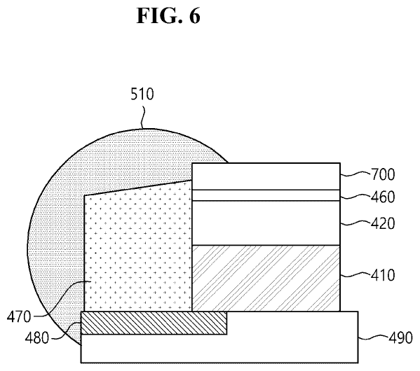

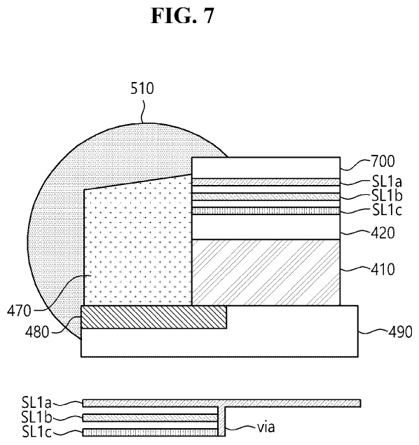

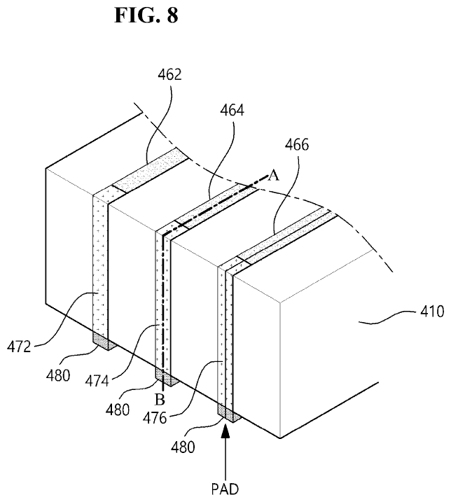

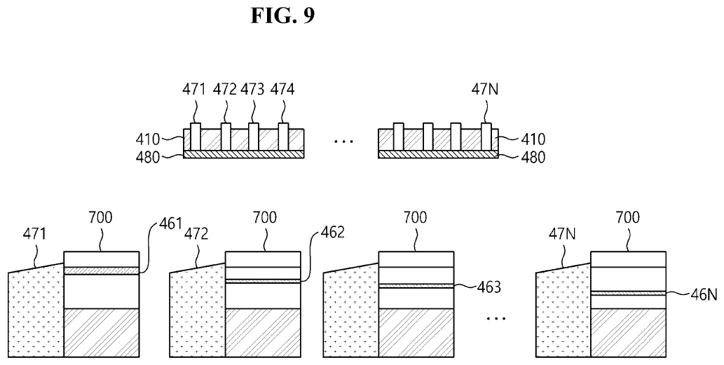

FIG. 5 is a cross-sectional view illustrating an example structure in the organic light emitting display device 100 according to aspects of the present disclosure. FIG. 6 is a cross-sectional view illustrating an example structure in a side portion of the organic light emitting display device according to aspects of the present disclosure. FIG. 7 is a cross-sectional view illustrating another example structure in a side portion of the organic light emitting display device according to aspects of the present disclosure. FIG. 8 is a perspective view of an example side portion of the organic light emitting display device according to aspects of the present disclosure. FIG. 9 illustrates an example structure in which different upper signal lines are connected to respective connection lines in the organic light emitting display device according to aspects of the present disclosure.

It should be noted here that for convenience of explanation, as shown in FIGS. 5 to 9, the organic light emitting display device 100 according to aspects of the present disclosure illustrate examples in which only an upper bezel area is removed (i.e., the upper bezel area is implemented to become zero). However, aspects of the present disclosure are not limited thereto. For example, when aspects (or examples) described below are applied to the display device 100, it may be realized that both the upper and lower bezel areas become almost zero or substantially zero.

Referring to the drawings, in some aspects, the organic light emitting display device 100 may include a panel assembly for displaying images, a flexible printed circuit board disposed on or under the lower surface of a substrate and connected to the panel assembly, and a connection line for interconnecting the panel assembly and the flexible printed circuit board. Hereinafter, the connection line may be referred to as a transmission line, a connection pad, or a transmission pad.

The panel assembly may include a TFT substrate 410 on which a display area AA is defined, a bottom pad 480 disposed on or under the lower surface of the TFT substrate 410, and a thin film encapsulation layer 440 disposed on the TFT substrate 410 while covering the display area AA, and be configured to display an image.

For example, a polyimide (PI) substrate may be used as the TFT substrate 410.

The thin film encapsulation layer 440 may be disposed on organic light emitting elements such as an organic light emitting diodes and driving circuits, which are disposed on the TFT substrate 410, and seal and protect the organic light emitting elements and driving circuits from external moisture or oxygen. An insulating layer 420 may be formed on the TFT substrate 410. Subpixels 430 may be disposed on the insulating layer 420.

A polarizing plate (not shown) may be disposed on the thin film encapsulation layer 440 to prevent reflection of light incident from the outside of the display device 100.

A cover glass 450 may be disposed on the thin film encapsulation layer 440.

A plurality of subpixels may be disposed in a matrix pattern in the display area AA of the TFT substrate 410.

The TFT substrate 410 may include a display area AA, a line area located on a side surface (or in a side portion or edge) of the TFT substrate 410 and including a plurality of connection lines 470 disposed at predetermined intervals, and a circuit area located on or under the lower surface of the TFT substrate 410 and allowing driving elements and other components for driving the panel assembly to be disposed.

For example, one or more connection lines 470 formed using a conductive material may be disposed in the line area. The display area AA on or over the upper surface of the TFT substrate 410 may be electrically connected with the circuit elements on or under the lower surface of the TFT substrate 410 through the one or more connection lines 470.

As shown in FIG. 8, the line area may be provided with a plurality of connection lines (470: 472, 474, 476) formed by coating a conductive material in engraved patterns formed on at least one side surface of the TFT substrate 410.

For example, one end of the conductive material coated in each of the engraved patterns in the line area may physically contact a corresponding upper signal line (460: 462, 464, 466) disposed on the upper surface of the TFT substrate 410.

The conductive material may be, for example, silver (Ag).

As shown in FIG. 9, in an aspect, a plurality of connection lines 470 may be disposed such that they are spaced apart from each other by a predetermined distance in a direction in which the side surface of the TFT substrate 410 horizontally extends. In this aspect, each upper signal line 460 may be connected to a corresponding connection line 470 among the plurality of connection lines 470. For example, on a one-to-one basis, one connection line 470 may be connected to one upper signal line 460, and another connection line 470 may be connected to another upper signal line 460.

As shown in FIG. 6, respective portions of a plurality upper signal lines 460 and respective connection lines 470 contacting the portions of the plurality upper signal lines 460 may be covered with a protective layer 510, and thus, may not be exposed to the outside.

The bottom pad 480 may be located at one end of the circuit area on the bottom substrate of the TFT substrate 410, and may be exposed to the outside. Pad electrodes for passing electrical signals to one or more scan drivers and one or more data drivers may be located on the bottom pad 480 of the TFT substrate 410.

A flexible printed circuit board 492 may be mounted on, or connected to, the bottom pad 480. One or more circuit devices 490 for processing driving signals may be mounted on the bottom pad 480 using the chip-on-film (COF) technique, and at least one connector (not shown) may be disposed in the bottom pad 480 to transmit external signals to the flexible printed circuit board 492.

The flexible printed circuit board 492 and the one or more circuit devices 490 may be disposed in the circuit area on the lower surface of the TFT substrate 410, which may be the lower surface of the panel assembly.

For example, in a situation where the thin film encapsulation layer 440 is bonded to the TFT substrate 410 to form a module assembly, the flexible printed circuit board 492 may be mounted at a lower portion of the organic light emitting display device 100 through the bottom pad 480 (e.g., the lower surface of the TFT substrate 410 or the lower surface of the panel assembly).

In this example, an anisotropic conductive film may be used to electrically connect a terminal part of the TFT substrate 410 and a connection part of the flexible printed circuit board 492 to each other.

The connection lines 470 may be provided on at least one of the upper, lower, left side, and right side surfaces of the TFT substrate 410, and for example, the connection lines 470 disposed on the upper surface of the TFT substrate 410 may be connected to the bottom pad 480 disposed on the lower surface of the TFT substrate 410.

As examples, FIG. 6 shows one upper signal line 460 disposed in the display device 100, and FIG. 7 shows a plurality of upper signal lines 460 disposed in the display device 100. Referring to FIG. 7, in one or more aspects, the plurality of upper signal lines 460 may include a first signal line SL1a, a second signal line SL1b, and a third signal line SLlc, which may be disposed in different layers and be electrically connected to the connection line 470, which are a conductor located on the side of the TFT substrate 410 (or the panel assembly).

In these aspects, the first signal line SL1a, the second signal line SL1b, and the third signal line SL1c may be respective parts of one signal line SL1. Thus, this implementation may provide an advantage of reducing contact resistance, compared with the configuration of the signal line shown in FIG. 6.

As shown in FIG. 7, even when the first signal line SLla, the second signal line SL1b, and the third signal line SL1c are disposed in different layers, they may be electrically connected to each other through a conductive material formed in through holes penetrating different layers. Thus, the first signal line SL1a, the second signal line SL1b, and the third signal line SL1c may serve as one signal line.

By applying the aspects described above to display devices, a narrow bezel may be realized to minimize the bezel area, and such a narrow bezel may be applied not only to the left and right bezels but also to the top and bottom bezels.

For example, although a bezel area in which driving elements and other components for display driving are disposed is defined in the panel assembly, and such driving elements and other components are needed to be located in the panel assembly, as essential element, it is desirable to minimize the bezel area because the bezel area is unnecessary in terms of product design.

According to the aspects described above, substantial zero bezel may be realized by disposing the driving elements and other components in the circuit area located on the lower surface of the TFT substrate rather than disposing in the bezel area.

Thus, realizing the substantial zero bezel may lead to design innovation in future display products, and may provide an effect of becoming a standard for all displays that implement zero bezel.

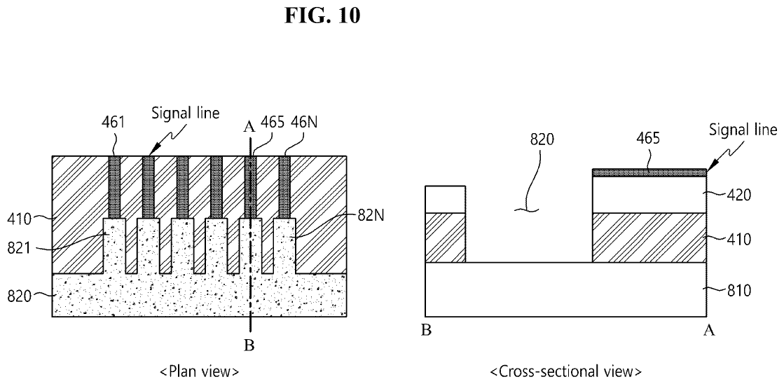

FIGS. 10 to 14 illustrate example process diagrams for explaining a method of manufacturing the organic light emitting display device 100 according to aspects of the present disclosure.

Referring to FIG. 10, in one or more aspects, to manufacture the organic light emitting display device 100, a glass substrate 810 may be disposed on the lower surface of a TFT substrate 410, and then, engraved patterns 820 may be formed at least a portion of the TFT substrate 410.

In one aspect, the engraved patterns (820: 821 to 82N, where N is an integer greater than 1) may be formed by spacing apart from each other at a predetermined distance in a direction in which a side surface of the TFT substrate 410 horizontally extends. In this aspect, locations and widths of the engraved patterns (820: 821 to 82N) may be determined and formed such that one end of each of the engraved patterns (820: 821 to 82N) is corresponded to a corresponding one of upper signal lines (460: 461 to 46N).

For example, each of the engraved patterns (820: 821 to 82N) may be formed in a line extending in the same direction on the same plane as a corresponding one of the upper signal lines (460: 461 to 46N), and may be formed with a width equal to or greater than the corresponding upper signal line. Here, the same plane may be the upper surface of the TFT substrate 410. The engraved patterns 820 may be formed extending from the upper surface of the TFT substrate 410 to a side surface thereof. For example, the engraved patterns 820 may be formed perpendicularly from the upper surface of the TFT substrate 410 to the side surface of the TFT substrate 410.

To form the engraved patterns 820, a dry etching process may be used on the TFT substrate 410.

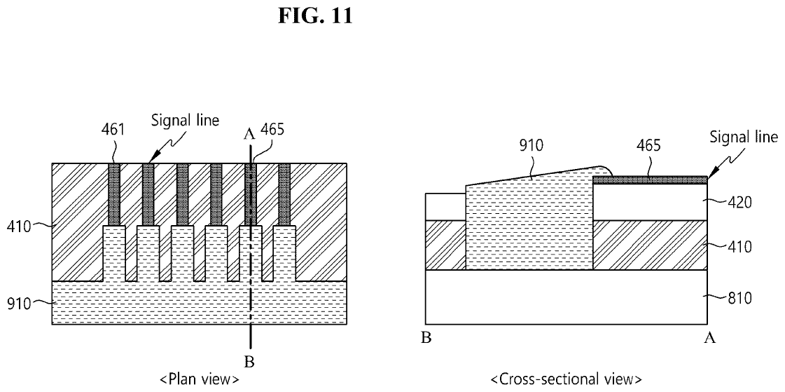

Next, as shown in FIG. 11, a conductive material 910 may be coated on the engraved patterns 820 formed on the TFT substrate 410, thus, the engraved patterns being filled with the conductive material. The conductive material may be, for example, silver (Ag). Further, any material that may be electrically connected to the upper signal lines 460 may be used as the conductive material.

The connection lines (470: 471, 472, 473, 474, . . . , 47N) may be formed by filling the conductive material 910 in each of the engraved patterns (820: 821 to 82N). After each of the engraved patterns (820: 821 to 82N) is filled with the conductive material 910, the large-area conductive material is separated through laser trimming. Thereafter, pads may be formed on the lower surface of the TFT substrate 410 so that the pads may receive a signal from each upper signal line 460.

As shown in FIG. 9, the connection lines (470: 471, 472, 473, 474, . . . , 47N) may be disposed at a predetermined interval in the horizontal direction. Each of the connection lines (470: 471, 472, 473, 474, . . . , 47N) may be connected to a corresponding one of the upper signal lines (460: 461, 462, 463, 464, . . . , 460N)).

For example, on a one-to-one basis, one connection line 470 may contact, and be electrically connected to, one upper signal line 460, and another connection line 470 may contact, and be electrically connected to, another upper signal line 460.

An insulating layer 420 may be formed in at least one of a lower layer and an upper layer between which an upper signal line 460 is interposed, and an organic layer 700 may be formed on the uppermost layer of the resulting stack. For example, one or more layers contacting the upper signal line 460 may be layers having a different property from one or more other layers.

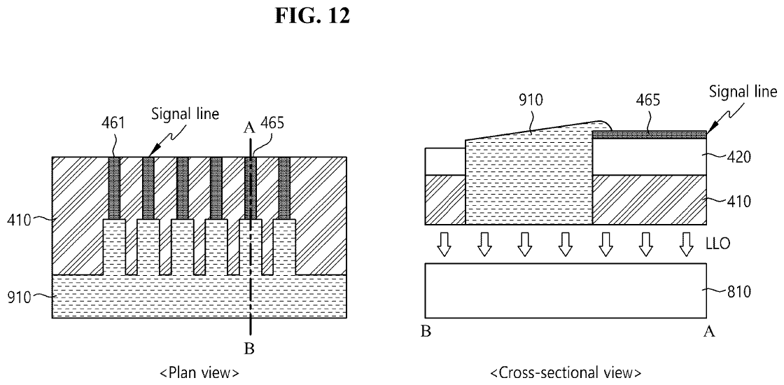

Referring to FIG. 12, after the plurality of connection lines 470 are formed, the glass substrate 810 used as a sacrificial layer may be removed through a laser lift-off (LLO) process. Thus, the glass substrate 810 may be removed from the TFT substrate 410.

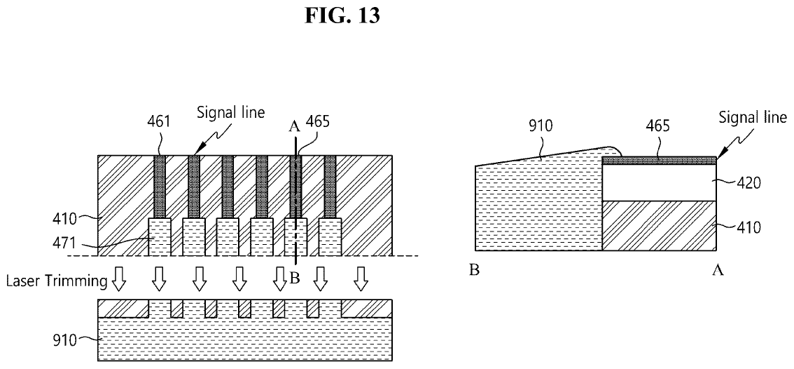

Next, referring to FIG. 13, pads formed of a conductive material allowing contact may be formed on the lower surface of the TFT substrate 410 by removing a lower portion of the TFT substrate 410 through laser trimming. These pads may serve as the connection lines (470: 471, 472, 473, 474, . . . , 47N). The conductive material 910, a portion of the TFT substrate 410, the insulating layer 420 on the portion of the TFT substrate 410, and the upper signal lines 465 may remain from such laser trimming. The upper signal line 465 may physically contact, and be electrically connected to, the conductive material 910.

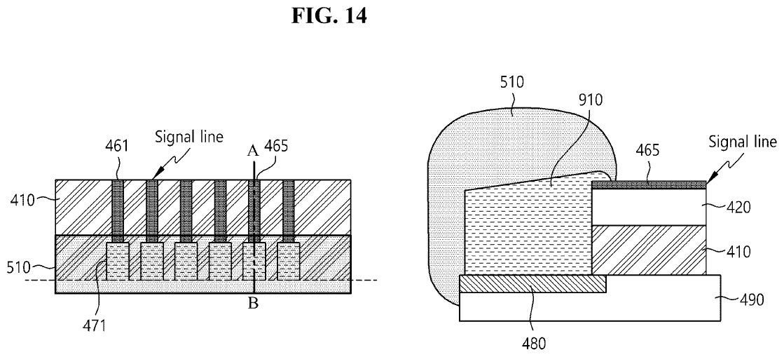

Next, referring to FIG. 14, circuit elements may be disposed on the lower surface of the TFT substrate 410 on which the pads (470: 471 to 47N) have been formed through the previous process using the chip-on-film (COF) technique. After the circuit elements are mounted on the lower surface of the TFT substrate 410, resin may be deposited to protect the pads (470: 471 to 47N).

For example, respective portions of the upper signal lines 460 and respective connection lines 470 contacting the upper signal lines 460 may be covered together by the protective layer 510. Thus, outer surfaces of the portions of the upper signal lines 460 and outer surfaces of the connection lines 470 contacting the upper signal lines 460 may not be exposed.

According to the one or more aspects described herein, an organic light emitting display device may be provided that is capable of minimizing, or almost eliminating, an area occupied by a side bezel area.

According to the one or more aspects described herein, an organic light emitting display device may be provided that is capable of reducing a bezel area without affecting display performance.

According to the one or more aspects described herein, an organic light emitting display device may be provided that is capable of reducing a bezel area without bending a TFT substrate.

According to the one or more aspects described herein, an organic light emitting display device may be provided that is capable of reducing production energy and manufacturing costs by disposing a connection line, which electrically interconnecting an upper signal line and circuit elements located under or on the lower surface of a TFT substrate, on a side of the TFT substrate through a simple process.

The aspects described above will be briefly described as follows.

According to the aspects described herein, an organic light emitting display device may be provided that includes: a panel assembly that includes a TFT substrate on which a display area is defined, a thin film encapsulation layer disposed on the TFT substrate such that the thin film encapsulation layer covers the display area, and a pad disposed on or under the lower surface of the TFT substrate, and is configured to displays an image; a flexible printed circuit board mounted on or bonded to the pad of the panel assembly; and a connection line that is disposed on at least one of the upper, lower, left side, and right side surfaces of the TFT substrate, and interconnects an upper signal line disposed on the upper surface of the TFT substrate and the pad disposed on or under the lower surface of the TFT substrate.

The TFT substrate may be formed of a polyimide (PI) substrate.

The TFT substrate may include a display area, a line area located on a side surface (or in a side portion or edge) of the TFT substrate and including a plurality of connection lines disposed at predetermined intervals, and a circuit area located on or under the lower surface of the TFT and allowing driving elements and other components for driving the panel assembly to be disposed.

One or more connection lines formed using a conductive material may be disposed in the line area. The display area on or over the upper surface of the TFT substrate may be electrically connected with the circuit area on or under the lower surface of the TFT substrate through the one or more connection lines.

The line area may be provided with connection lines formed by coating a conductive material in engraved patterns formed on at least one side surface of the TFT substrate.

The conductive material may be, for example, silver (Ag). One end of the conductive material coated in each of the engraved patterns in the line area may physically contact a corresponding upper signal line disposed on the upper surface of the TFT substrate.

The connection lines may be disposed at a predetermined interval in a direction in which the TFT substrate horizontally extends. Each of the connection lines may be connected to a corresponding one of the upper signal lines.

Outer surfaces of respective connection lines contacting the upper signal lines and outer surfaces of respective portions of the upper signal lines may be covered together by a protective layer, and thus, may not be exposed.

The flexible printed circuit board may be mounted in a lower portion, or on the lower surface, of a panel assembly through an anisotropic conductive film.

The above description has been presented to enable any person skilled in the art to make, use and practice the technical features of the present disclosure, and has been provided in the context of a particular application and its requirements as examples. Various modifications, additions and substitutions to the described aspects will be readily apparent to those skilled in the art, and the principles described herein may be applied to other aspects and applications without departing from the scope of the present disclosure. Thus, it is intended that the present disclosure covers the modifications and variations of the aspects provided they come within the scope of the appended claims and their equivalents.

What is claimed is:

1. An organic light emitting display device comprising:
a panel assembly that comprises a thin film transistor (TFT) substrate on which a display area is defined, a thin film encapsulation layer disposed on the TFT substrate such that the thin film encapsulation layer covers the display area, and a bottom pad disposed on a lower surface of the TFT substrate, and is configured to displays an image;
a flexible printed circuit board mounted on the bottom pad of the panel assembly; and
a connection line that is disposed on at least one of upper, lower, left side, and right side surfaces of the TFT substrate, and interconnects an upper signal line disposed on the upper surface of the TFT substrate and the bottom pad disposed on the lower surface of the TFT substrate.

2. The organic light emitting display device of claim 1, wherein the TFT substrate is formed of a polyimide (PI) substrate.

3. The organic light emitting display device of claim 1, wherein the TFT substrate comprises:
a display area;
a line area located on a side surface of the TFT substrate and including a plurality of connection lines disposed at predetermined intervals; and
a circuit area located on the lower surface of the TFT substrate and allowing driving elements and other components for driving the panel assembly to be disposed.

4. The organic light emitting display device of claim 3, wherein the connection lines included in the line area are formed by using a conductive material, and the connection lines electrically interconnect the display area on the upper surface of the TFT substrate and the circuit area on the lower surface of the TFT substrate.

5. The organic light emitting display device of claim 3, wherein the connection lines included in the line area are formed by coating of a conductive material in engraved patterns formed on the side surface of the TFT substrate.

6. The organic light emitting display device of claim 5, wherein the conductive material comprises silver (Ag).

7. The organic light emitting display device of claim 5, wherein the line area is formed such that one end of the conductive material coated in any one of the engraved patterns physically contacts the upper signal line disposed on the upper surface of the TFT substrate.

8. The organic light emitting display device of claim 7, wherein the connection lines are disposed such that the connection lines are spaced apart from each other by a predetermined distance in a direction in which the side surface of the TFT substrate horizontally extends, and each of upper signal lines is connected to a corresponding connection line among the connection lines.

9. The organic light emitting display device of claim 8, wherein outer surfaces of respective connection lines contacting the upper signal lines and outer surfaces of respective portions of the upper signal lines are covered together by a protective layer, and are not exposed.

10. The organic light emitting display device of claim 1, wherein the flexible printed circuit board is mounted in a lower portion, or on a lower surface, of the panel assembly through an anisotropic conductive film.

11. An organic light emitting display device comprising:
an upper signal line disposed on a upper surface of a thin film transistor (TFT) substrate;
a circuit device located on a lower surface of the TFT substrate, and including a driving element and other components for driving a panel assembly; and
a connection line disposed on a side surface of the TFT substrate, and interconnecting the upper signal line and the circuit device.

12. The organic light emitting display device of claim 11, wherein the TFT substrate is formed of a polyimide (PI) substrate.

13. The organic light emitting display device of claim 11, wherein the connection line is formed by using a conductive material, and the connection line electrically interconnects a display area on the upper surface of the TFT substrate and a circuit area on the lower surface of the TFT substrate.

14. The organic light emitting display device of claim 13, wherein the connection line is formed by coating of the conductive material in an engraved pattern formed on the side surface of the TFT substrate.

15. The organic light emitting display device of claim 14, wherein the conductive material comprises silver (Ag).

16. The organic light emitting display device of claim 14, wherein the connection line is disposed such that one end of the conductive material coated in the engraved pattern physically contacts the upper signal line.

17. The organic light emitting display device of claim 16, wherein connection lines are disposed such that the connection lines are spaced apart from each other by a predetermined distance in a direction in which the side surface of the TFT substrate horizontally extends, and each of upper signal lines is connected to a corresponding connection line among the connection lines.

18. The organic light emitting display device of claim 17, wherein outer surfaces of respective connection lines contacting the upper signal lines and outer surfaces of respective portions of the upper signal lines are covered together by a protective layer, and are not exposed.

19. The organic light emitting display device of claim 11, wherein further comprising a flexible printed circuit board,
the flexible printed circuit board is mounted in a lower portion, or on a lower surface, of the panel assembly through an anisotropic conductive film.
